(19) United States
(12) Patent Application Publication
(10) Pub. No.: US 2009/0032885 A1
(43) Pub. Date: Feb. 5, 2009

(54) Buried Isolation Layer

(75) Inventor: Michael Church, Sebastian, FL (US)

Correspondence Address: BARNES & THORNBURG LLP, 750-17TH STREET NW, SUITE 900, WASHINGTON, DC, 20006-4675, US

(73) Assignee: INTERSIL AMERICAS, INC., Milipitas, CA (US)

(21) Appl. No.: 11/877,166

(22) Filed: Oct. 23, 2007

Related U.S. Application Data
(60) Provisional application No. 60/952,971, filed on Jul. 31, 2007.

(51) Int. Cl. H01L 29/78; H01L 29/00

(52) U.S. Cl. 257/394; 257/544; 257/552; 257/E29.001; 257/E29.255

(57) ABSTRACT

The present disclosed integrated circuit includes a substrate having a top surface, a buried N type layer in the substrate, N type contact region extending from the surface to the buried N type region, a buried P type region abutting and above the buried N type region in the substrate, a P type contact region extending from the surface to the buried P type region, and an N type device region in the surface and above the buried P type region. The P type impurity of the buried P type region including an impurity of a lower coefficient of diffusion than the coefficient of diffusion of the impurities of the P type contact region.

### BACKGROUND AND SUMMARY

The present disclosure relates to integrated circuit and more specifically to buried junction isolation for integrated circuits.

Subsurface layers are used to define the bottom portion of isolation junctions for many structures in integrated circuits. Multiple layers of alternating conductivity are sometimes stacked vertically to meet the isolation needs of processes such as CMOS and/or DMOS processes used to build mixed signal and power management circuits.

The layers in these processes should be kept as thin as possible while still meeting the required voltages so as to minimize area wasting side diffusion of the edges of the layers.

An example of a critical subsurface layer whose thickness must be minimized is the P isolation layer in the lateral NMOS structure illustrated in FIG. 1. Such a device may be required to provide isolation between the N− region in which the drain is formed and the N layer below the P isolation layer when the N layer is at 24 volts, the drain contact is at −5 volts and the P isolation layer is at 0 volts and the P Substrate is at 0 volts. An added benefit of this alternating N and P layer combination is that when the drain contact is −5 volts, the drain contact region is forward biased with respect to the P isolation layer and not the P substrate. Therefore, little or no current is injected into the P substrate and superior crosstalk noise isolation is attained.

The P isolation layers in the prior art have been made using boron. The relatively high diffusion coefficient of boron results in up diffusion of the layer into the overlying N layer during subsequent steps. The subsequent steps may include the diffusion of the P regions that connect the P isolation layer to the surface and/or the diffusion of N regions that connect the N buried layer to the surface.

The up diffusion limits the breakdown voltage between the N+ drain contact and the P isolation layer or alters the device performance in some negative manner. The breakdown can be increased by thickening the N− layer but this requires more diffusion of the lateral P isolation and lateral N sinkers and increases undesirable side diffusion.

This disclosure describes a process and resulting structure that improve on the process and structure described above. The improvement is obtained by using indium entirely or partially rather than boron only for the P isolation layer dopant. The diffusion coefficient of indium is only about 0.25 that of boron at a given temperature. Consequently up diffusion is significantly reduced.

Indium has not been previously considered for applications like buried layers because most of the dopant freezes out and is electrically inactive at normal device operating temperatures as described in “Silicon NPN Bipolar Transistors with Indium-Implanted Base Regions” by I. C. Kizilyalli et. al. IEEE Electron Device Letters vol. 18, No. 3, March 1997 pp. 120-123. As a result of the freeze out, the resistivity of the layer can be over ten times that that would be expected from the doping concentration even at room temperature and much worse than that at low temperature.

The present disclosed integrated circuit includes a substrate having a top surface, a buried N type layer in the substrate, N type contact region extending from the surface to the buried N type region, a buried P type region abutting and above the buried N type region in the substrate, a P type contact region extending from the surface to the buried P type region, and an N type device region in the surface and above the buried P type region. The P type impurity of the buried P type region including an impurity of a lower coefficient of diffusion than the coefficient of diffusion of the impurities of the P type contact region. The P type impurity of the buried P type region is entirely or partially indium.

The N type buried region and the P type buried region are bottom junction isolation regions. The N type contact region and the P type contact region may be concentric lateral junction isolation regions. The substrate may include a P type layer with an N or P type epitaxial layer thereon, and the top surface is on the epitaxial layer.

The N type device region may be a drain region of a field effect transistor; and a P type body region separates an N type source region from the N type drain region in the substrate. The N type device region may be a collector region of a bipolar transistor; and a P type base region separates an N type emitter region from the N type collector region in the substrate.

These and other aspects of the present disclosure will become apparent from the following detailed description of the disclosure, when considered in conjunction with accompanying drawings.

### BRIEF DESCRIPTION OF DRAWINGS

FIG. 1 is cross-sectional view of an integrated circuit having a lateral NMOS with the buried layer junction isolation of the present disclosure.

FIG. 2 is cross-sectional view of another integrated circuit with the buried layer junction isolation of the present disclosure.

FIG. 3 is cross-sectional view of another integrated circuit having a bipolar transistor with the buried layer junction isolation and lateral dielectric isolation of the present disclosure.

### DETAILED DESCRIPTION OF THE PREFERRED EMBODIMENTS

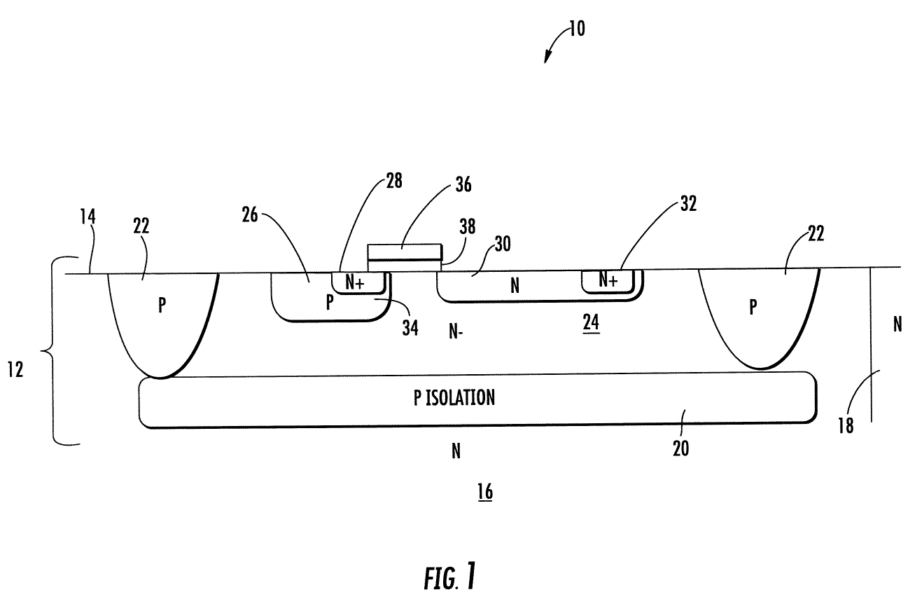

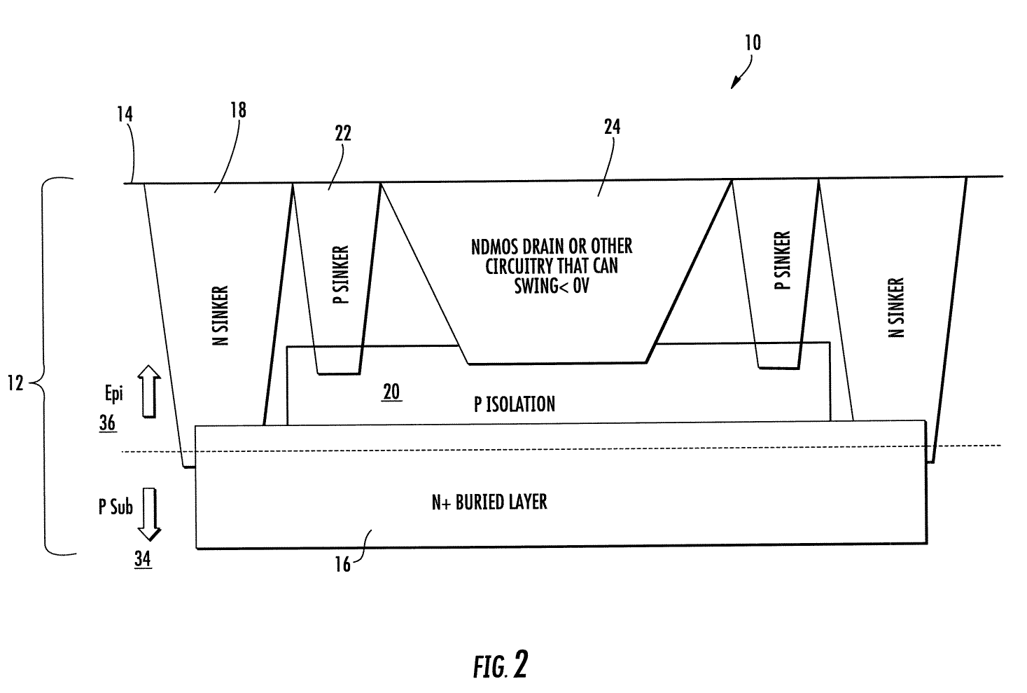

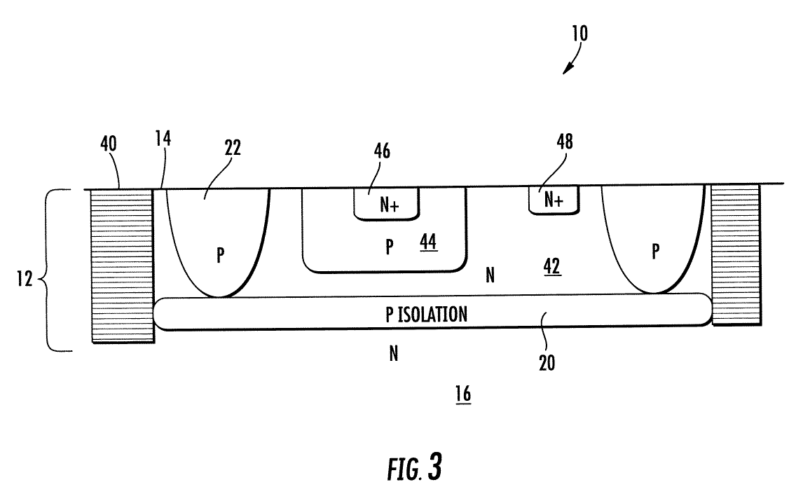

An integrated circuit 10 of FIGS. 1 through 3 includes a substrate 12 having an N-buried layer 16 with an abutting P isolation layer 20. In FIG. 2, the substrate 12 includes a substrate 34 with an epitaxial layer 36. P contact regions 22 extends from the surface 14 of the substrate down to the P isolation layer 20. In FIGS. 1 and 2, an N contact region 18 extends from the surface 14 of the substrate down to the N buried layer 16. In FIG. 3, the contact to the N buried layer 16 is not shown. The N type device region 24 in FIGS. 1 and 2 and region 42 in FIG. 3 extend from the top surface 14 above the buried P region 20.

In all embodiments, the P isolation region 20 impurity is indium entirely or partially with some boron. The diffusion coefficient of indium is only about 0.25 that of boron at a given temperature. Consequently up diffusion is significantly reduced. This allows build devices with reduced foot print or die space. Although at least 50% indium is a targeted range, less than 20% indium may not be economically justified. Other combination of P type impurities may be used, for example indium with aluminum or boron with aluminum. The P contact regions 22 to the buried isolation layer 20 may be boron.

In FIG. 1, the device is an N type integrated field effect transistor wherein the N region 24 is the drain that includes a P body region 26 in the drain region 24 and an N+ source region 28 in the P body region 26. In the example shown, there is an N drain extension 30 in the drain region 24 and a drain contact 32 in the drain extension 30. The drain extension 30 may be eliminated. A gate region 36 is separated from the channel region 34 by an insulation layer 38.

In the example of FIG. 3, a bipolar transistor is shown wherein the N device region 42 is the collector region having a P type base region 44 therein and then N+ emitter region 46 in the base region 44. N+ collector contact region 48 is provided in the collector region 42.

While FIGS. 1 and 2 show a generic N type layer 16, FIG. 2 shows a specific embodiment wherein the substrate 12 includes a first P type layer 34 with an N or P type epitaxial layer 36 thereon. The buried region 16 is formed in the P layer 34 prior to the epitaxial layer 36 being provided thereon. The isolation region 20 is formed in the epitaxial layer 36.

In FIGS. 1 through 3, the N region 16 and the P region 20 are buried junction isolation regions for the device in the integrated circuit. In FIG. 2, the N contact region 18 and the P contact region 22 are concentric and form lateral junction isolations. In contrast, in FIG. 3, lateral isolation is provided by dielectric regions 40.

Structural variations that retain the present P isolation layer are possible. The N− layer 24,42 above the P isolation layer 20 could be a P layer in applications where the NMOS body 26 and P isolation layer 20 are at the same voltage. The component formed above the P isolation layer 20 could be something other an NMOS such as but not limited to an NPN.

As noted by Kizilyalli, the portion of an indium doped layer contained in a depleted region is fully ionized. As a result of this property, an indium doped layer provides the same amount of electrical blocking that a similar doping profile of boron provides. Thus indium can provide the P isolation layer with no loss of electrical isolation despite its propensity to freeze out.

The series resistance of the indium layer made with a given doping concentration will be much higher than that of a similarly doped boron layer. The resistance that arises from the difference in resistivity can be managed by controlling the number of squares on the parasitic resistor as part of the geometry design. A combination of boron and indium for the P isolation layer 20 provides the best of both worlds. Boron allows lower sheet resistance than indium alone while indium allows more blocking voltage than boron alone without sacrificing footprint.

Although the present disclosure had been described and illustrated in detail, it is to be clearly understood that this is done by way of illustration and example only and is not to be taken by way of limitation. The scope of the present disclosure is to be limited only by the terms of the appended claims.

What is claimed:

1. An integrated circuit comprising:
a substrate having a top surface, a buried N type layer in the substrate, N type contact region extending from the surface to the buried N type region, a buried P type region abutting and above the buried N type region in the substrate, a P type contact region extending from the surface to the buried P type region, and an N type device region in the surface and above the buried P type region; and
the P type impurity of the buried P type region being at least partially indium.

2. The integrated circuit according to claim 1, wherein the N type buried region and the P type buried region are bottom junction isolation regions.

3. The integrated circuit according to claim 2, wherein the N type contact region and the P type contact region are concentric lateral junction isolation regions.

4. The integrated circuit according to claim 1, wherein the substrate includes a P type layer with and an epitaxial layer thereon, and the top surface is on the epitaxial layer.

5. The integrated circuit according to claim 1, wherein the N type device region is a drain region of a field effect transistor; and including a P type body region separating an N type source region from the N type drain region in the substrate.

6. The integrated circuit according to claim 1, wherein the N type device region is a collector region of a bipolar transistor; and including a P type base region separating an N type emitter region from the N type collector region in the substrate.

7. The integrated circuit according to claim 1, wherein the P type impurity of the buried P type region indium and boron.

8. An integrated circuit comprising:
a substrate having a top surface, a buried N type layer in the substrate, N type contact region extending from the surface to the buried N type region, a buried P type region abutting and above the buried N type region in the substrate, a P type contact region extending from the surface to the buried P type region, and an N type device region in the surface and above the buried P type region; and
the P type impurity of the buried P type region including an impurity of a lower coefficient of diffusion than the coefficient of diffusion of the impurities of the P type contact region.

9. The integrated circuit according to claim 8, wherein the P type impurity of the buried P type region being at least partially indium.
